(19) United States
(12) Patent Application Publication
(10) Pub. No.: US 2017/0018625 A1
(43) Pub. Date: Jan. 19, 2017

(54) TRANSISTOR INCLUDING TOPOLOGICAL INSULATOR

(71) Applicant: KOREA INSTITUTE OF SCIENCE AND TECHNOLOGY, Seoul (KR)

(72) Inventors: Hyun Cheol KOO, Seoul (KR); Hyung-jun KIM, Seoul (KR); Jun Woo CHOI, Seoul (KR); Joonyeon CHANG, Seoul (KR); Suk Hee HAN, Seoul (KR); Chaun JANG, Seoul (KR); Youn Ho PARK, Seoul (KR)

(73) Assignee: KOREA INSTITUTE OF SCIENCE AND TECHNOLOGY, Seoul (KR)

(21) Appl. No.: 15/193,571

(22) Filed: Jun. 27, 2016

(30) Foreign Application Priority Data
Jul. 15, 2015 (KR) 10-2015-0100581

(51) Int. Cl. H01L 29/51; H01L 29/417; H01L 29/423

(52) U.S. Cl. CPC H01L 29/516; H01L 29/42364; H01L 29/41775

(57) ABSTRACT

Disclosed is a transistor including a topological insulator. The transistor includes: a substrate; a topological insulator provided on the substrate; a drain electrode provided on the topological insulator; a source electrode separated from the drain electrode, provided on the topological insulator, and including a ferromagnetic substance; a tunnel junction layer provided on the source electrode; and a gate electrode provided on the tunnel junction layer. A spin direction of the topological insulator is fixed by a current flowing to a surface thereof, and a spin direction of the source electrode is changed to a predetermined direction by a voltage applied to the gate electrode.

### CROSS-REFERENCE TO RELATED APPLICATION

This application claims priority to and the benefit of Korean Patent Application No. 10-2015-0100581 filed in the Korean Intellectual Property Office on Jul. 15, 2015, the entire contents of which are incorporated herein by reference.

### BACKGROUND OF THE INVENTION

(a) Field of the Invention

The present invention relates to a transistor. Particularly, the present invention relates to a transistor including a topological insulator.

(b) Description of the Related Art

A topological insulator represents a topological state of a material or a material with such a state. The topological insulator is divided into a topological insulator with a strong correlation between electrons as a cause in a like manner of a quantum Hall system, and a band topological insulator with a band structure as a cause. The topological insulator, differing from general materials, depends on topological characteristics and has no connection to local and external perturbation.

The topological insulator corresponds to a semiconductor or an insulator with an energy gap, and a surface state has a metal characteristic without an energy gap. Therefore, various types of products having the characteristic of the topological insulator applied thereto have been developed. For example, topological quantum computers and memories correspond thereto.

The above information disclosed in this Background section is only for enhancement of understanding of the background of the invention and therefore it may contain information that does not form the prior art that is already known in this country to a person of ordinary skill in the art.

### SUMMARY OF THE INVENTION

The present invention has been made in an effort to provide a transistor manufactured using a topological insulator.

An exemplary embodiment of the present invention provides: a substrate; a topological insulator provided on the substrate; a drain electrode provided on the topological insulator; a source electrode separated from the drain electrode, provided on the topological insulator, and including a ferromagnetic substance; a tunnel junction layer provided on the source electrode; and a gate electrode provided on the tunnel junction layer.

A spin direction of the topological insulator is fixed by a current flowing to a surface thereof, and a spin direction of the source electrode is changed to a predetermined direction by a voltage applied to the gate electrode.

An angle formed between the predetermined direction and the spin direction may be 0°, 90°, or 180°.

When a voltage is not applied to the gate electrode, a spin direction of the source electrode may be opposite a spin direction of the topological insulator, and when the voltage is applied to the gate electrode, the spin direction of the source electrode may correspond to the spin direction of the topological insulator.

The transistor may be operated as an n-type transistor or a p-type transistor by a spin direction of the gate electrode and an initial spin direction of the source electrode.

When the transistor is an n-type-like transistor and a voltage is not applied to the gate electrode, a spin direction of the source electrode may form 90° with a spin direction of the topological insulator, and when the voltage is applied to the gate electrode, the spin direction of the source electrode may correspond to the spin direction of the topological insulator.

When the transistor is a p-type-like transistor and a voltage is not applied to the gate electrode, a spin direction of the source electrode may form 90° with a spin direction of the topological insulator, and when the voltage is applied to the gate electrode, the spin direction of the source electrode may correspond to the spin direction of the topological insulator.

The topological insulator may include at least one material selected from Bi₂Se₃, Bi₂Te₃, and Ag₂Te₃.

The transistor is manufactured by use of the topological insulator so the structure of the transistor may be simplified. Therefore, the transistor may be manufactured with a low cost.

### BRIEF DESCRIPTION OF THE DRAWINGS

FIG. 1 shows a perspective view of a transistor according to a first exemplary embodiment of the present invention.

FIG. 2A and FIG. 2B show operational state diagrams of a transistor of FIG. 1.

FIG. 3A and FIG. 3B show other operational state diagrams of a transistor of FIG. 1.

FIG. 4 shows a perspective view of a transistor according to a second exemplary embodiment of the present invention.

FIG. 5A and FIG. 5B show operational state diagrams of a transistor of FIG. 4.

FIG. 6A and FIG. 6B show other operational state diagrams of a transistor of FIG. 4.

### DETAILED DESCRIPTION OF THE EMBODIMENTS

It will be understood that, although the terms first, second, third, etc. may be used herein to describe various elements, components, regions, layers, and/or sections, they are not limited thereto. These terms are only used to distinguish one element, component, region, layer, or section from another element, component, region, layer, or section. Thus, a first element, component, region, layer, or section discussed below could be termed a second element, component, region, layer, or section without departing from the teachings of the present invention.

The technical terms used herein are to simply mention a particular exemplary embodiment and are not meant to limit the present invention. An expression used in the singular encompasses the expression of the plural, unless it has a clearly different meaning in the context. In the specification, it is to be understood that the terms such as “including”, “having”, etc., are intended to indicate the existence of specific features, regions, numbers, stages, operations, elements, components, or combinations thereof disclosed in the specification, and are not intended to preclude the possibility that one or more other specific features, regions, numbers, operations, elements, components, or combinations thereof may exist or may be added.

Unless otherwise defined, all terms used herein, including technical or scientific terms, have the same meanings as those generally understood by those with ordinary knowledge in the field of art to which the present invention belongs. Such terms as those defined in a generally used dictionary are to be interpreted to have the meanings equal to the contextual meanings in the relevant field of art, and are not to be interpreted to have idealized or excessively formal meanings unless clearly defined in the present application.

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

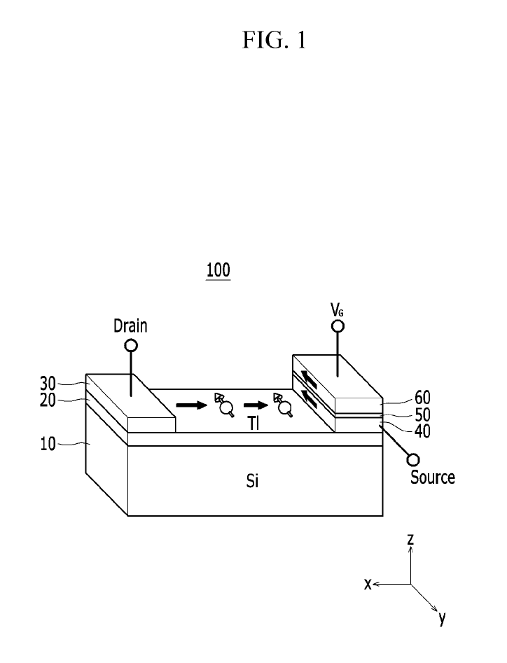

FIG. 1 shows a perspective view of a transistor 100 according to a first exemplary embodiment of the present invention. A configuration of the transistor 100 shown in FIG. 1 exemplifies the present invention, but the present invention is not restricted thereto. Therefore, the configuration of the transistor 100 may be modified in many ways.

As shown in FIG. 1, the transistor 100 includes a substrate 10, a topological insulator (TI) 20, a drain electrode 30, a source electrode 40, a tunnel junction layer 50, and a gate electrode 60. The transistor 100 may further include another layer. The transistor 100 is operable in a like manner of an n-type transistor.

Silicon (Si) is used as a material of the substrate 10. The silicon is used as a basic material when a semiconductor element is manufactured. The topological insulator 20 is formed on the substrate 10. Bi₂Se₃, Bi₂Te₃, or Ag₂Te₃may be used as a material for the topological insulator 20. A current flows on a surface of the topological insulator 20. A spin may be aligned in a specific direction because of such a characteristic of the topological insulator 20. As a result, the spin direction of the source electrode 40 is controllable by a gate voltage (VG) input through the gate electrode 60. For this purpose, a ferromagnetic substance is used as a material of the source electrode 40. The tunnel junction layer 50, an insulator, is provided on the source electrode 40, and the gate electrode 60 is provided on the tunnel junction layer 50. The gate electrode 60 uses a specific material to fix the spin direction. The spin direction of the gate electrode 60 must not be changed during its operation, so the source electrode 40 uses a ferromagnetic substance with a coercive force that is less than that of the gate electrode 60. Therefore, the spin direction of the source electrode 40 changes according to a voltage (VG) applied to the gate electrode 60, so a different output value may be acquired through the drain electrode 30 by using the change. Here, the gate electrode 60 is manufactured to extend long along a −y axis so that the transistor 100 may be operable like an n-type transistor.

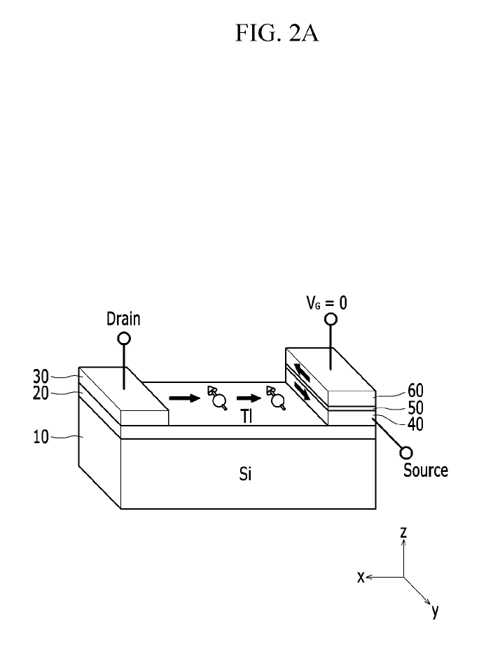

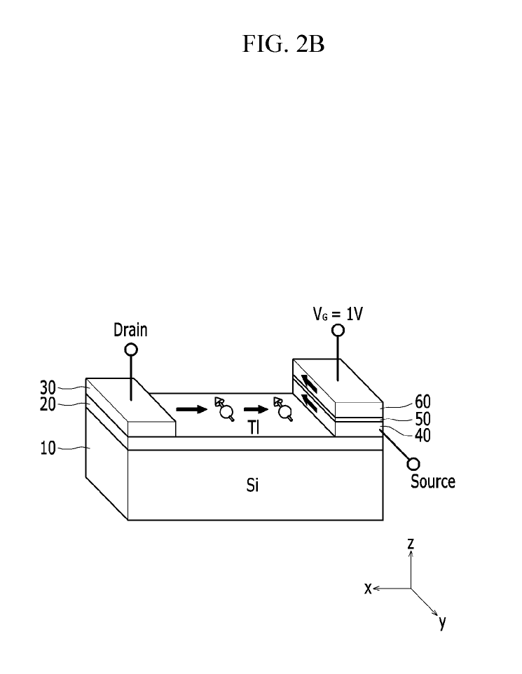

FIG. 2A and FIG. 2B show operational state diagrams of a transistor 100 of FIG. 1. An operational state of the transistor 100 exemplifies the present invention, but the present invention is not limited thereto. Therefore, the operational state of the transistor 100 may be modified.

Referring to FIG. 2A, the spin of the gate electrode 60 is aligned in the -y axis direction, and the direction is fixed while the transistor 100 is operated. The spin of the source electrode 40 is initially aligned in a +y axis direction, and the direction is changeable by the gate electrode 60.

As shown in FIG. 2A, when the spin of the topological insulator 20 is aligned toward the -y axis direction and a voltage is not applied to the gate electrode 60, the spin direction of the source electrode 40 maintains the +y axis direction that is the initial state and becomes opposite the spin of the topological insulator 20. In this case, the current does not flow through the drain electrode 30 and the source electrode 40. (Off state)

On the contrary, as shown in FIG. 2B, when the spin of the topological insulator 20 is aligned toward the −y axis direction and the voltage is applied to the gate electrode 60, the spin of the gate electrode 60 is transmitted to the source electrode 40 and is switched in the -y axis direction in parallel to the gate electrode 60. As a result, the spin of the source electrode 40 is aligned in the same direction as the spin of the topological insulator 20. Therefore, the current flows through the drain electrode 30. (On state)

When a magnetizing direction of the gate electrode 60 is aligned in the −y axis direction, the transistor 100 is turned off when the gate voltage is 0 volts, and the transistor 100 is turned on when it is 1 volt, so the transistor 100 is operated like an n-type transistor without doping.

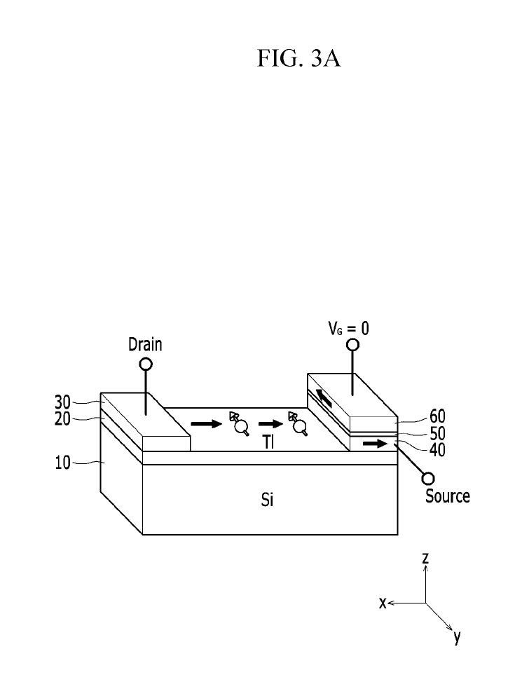

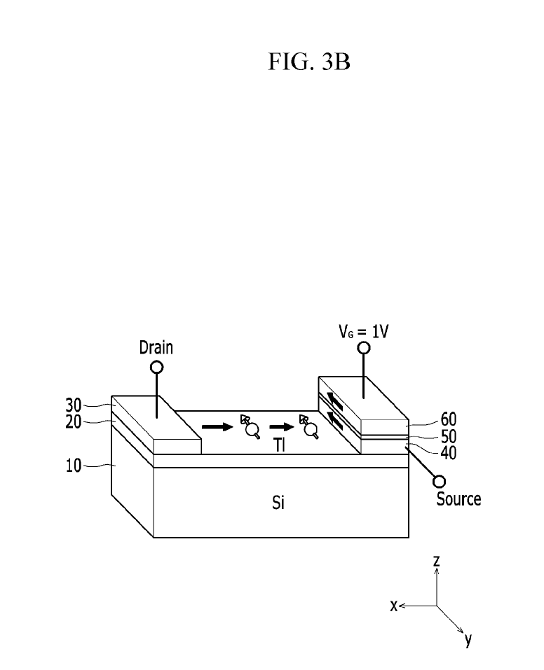

FIG. 3A and FIG. 3B show other operational state diagrams of a transistor 100 of FIG. 1. The operational state transistor 100 exemplifies the present invention, and the present invention is not restricted thereto. Therefore, the operational state of the transistor 100 may be modified.

Referring to FIG. 3A, the spin of the gate electrode 60 is aligned toward the −y axis direction, and the direction is fixed. The spin of the source electrode 40 is initially aligned in a +x axis direction, and the direction is changeable by the gate electrode 60.

As shown in FIG. 3A, when the spin of the topological insulator 20 is aligned toward the −y axis direction and a voltage is not applied to the gate electrode 60, the spin direction of the source electrode 40 maintains the −x axis direction that is the initial state and becomes orthogonal to the spin of the topological insulator 20. In this case, the current does not flow through the source electrode 40 and the drain electrode 30. (Off state)

On the contrary, as shown in FIG. 3B, when the spin of the topological insulator 20 is aligned toward the −y axis direction and the voltage is applied to the gate electrode 60, the spin of the gate electrode 60 is transmitted to the source electrode 40 and the spin of the source electrode 40 is switched in the −y axis direction in parallel to the gate electrode 60. As a result, the spin of the source electrode 40 is aligned in the same direction as the spin of the topological insulator 20. Therefore, the current flows through the source electrode 40 and the drain electrode 30. (On state)

As described above, the transistor 100 of FIG. 1 is turned off when the gate voltage is 0 volts, and the transistor 100 of FIG. 1 is turned on when the gate voltage is 1 volt so the transistor 100 is operated like an n-type transistor without doping.

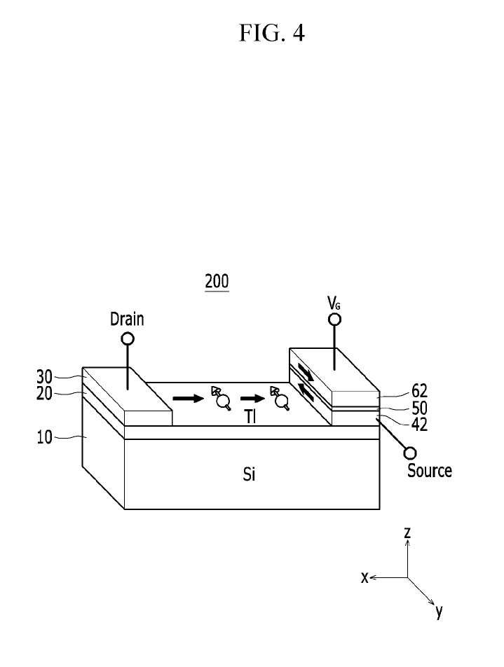

FIG. 4 shows a perspective view of a transistor 200 according to a second exemplary embodiment of the present invention. The configuration of the transistor 200 of FIG. 4 is similar to the configuration of the transistor 100 of FIG. 1 except for the gate electrode 62 and the source electrode 42 so like parts use like reference numerals and no detailed description thereof will be provided.

As shown in FIG. 4, the spin of the gate electrode 62 is aligned toward the +y axis direction, and the direction is fixed during its operation. The spin direction of the source electrode 42 is controllable according to the gate voltage (VG) input through the gate electrode 62. That is, the spin direction of the source electrode 42 changes according to the voltage (VG) applied to the gate electrode 62, so a different output value may be acquired through the drain electrode 30 by using the change. Here, the transistor 200 is operable like a p-type transistor so the gate electrode 62 may be aligned in the +y axis direction.

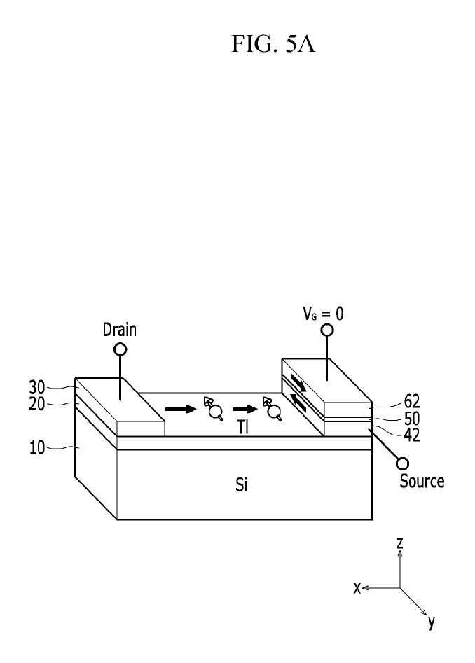

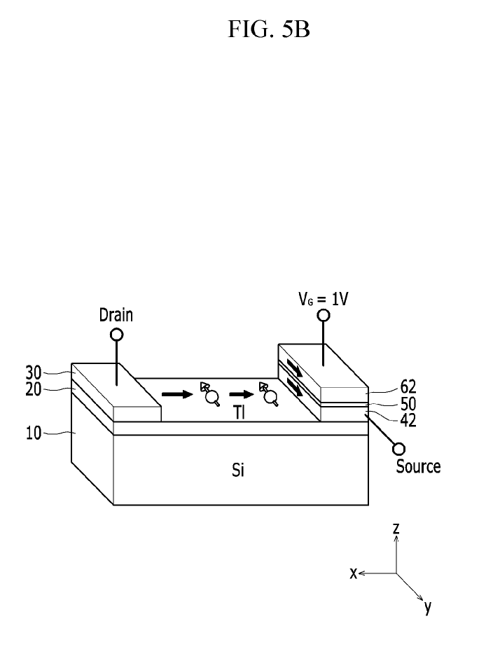

FIG. 5A and FIG. 5B show operational state diagrams of a transistor 200 of FIG. 4. An operational state of the transistor 200 exemplifies the present invention, but the present invention is not limited thereto. Therefore, the operational state of the transistor 200 may be modified.

Referring to FIG. 5A, the spin of the gate electrode 62 is aligned toward the +y axis direction, and the direction is fixed during its operation. The spin of the source electrode 42 is initially aligned in the −y axis direction, and the direction is changeable by the gate electrode 62.

As shown in FIG. 5A, when the spin of the topological insulator 20 is aligned toward the -y axis direction and the voltage is not applied to the gate electrode 62, the spin of the source electrode 42 maintains the −y axis direction that is an initial state. Therefore, the spin of the source electrode 42 is aligned in the same direction as the spin of the topological insulator 20. Hence, the current flows through the source electrode 42 and the drain electrode 30. (On state)

On the contrary, as shown in FIG. 5B, when the spin of the topological insulator 20 is aligned toward the −y axis direction and the voltage is applied to the gate electrode 62, the spin of the gate electrode 62 is transmitted to the source electrode 42 and is switched in the +y axis direction in parallel to the gate electrode 62. As a result, the spin of the source electrode 42 is aligned in an opposite direction of the spin of the topological insulator 20. Therefore, the current does not flow through the source electrode 42 and the drain electrode 30. (Off state)

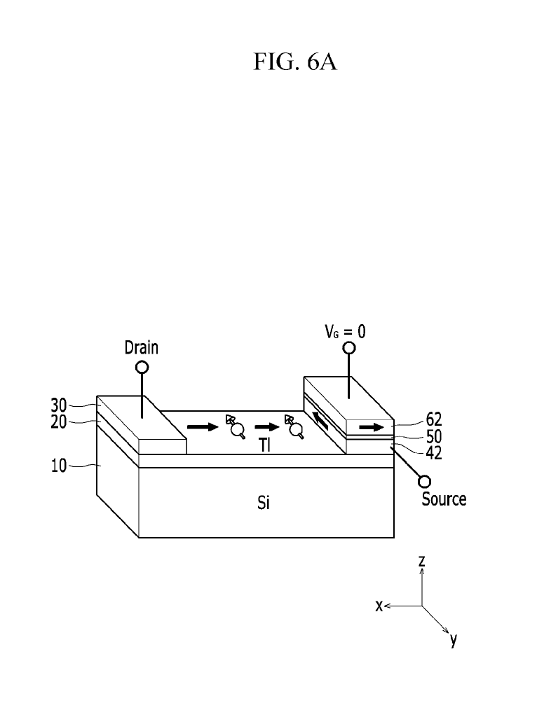

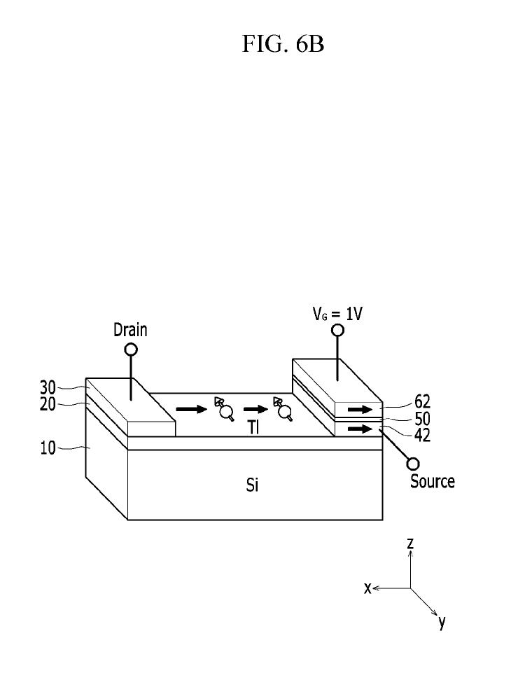

FIG. 6A and FIG. 6B show other operational state diagrams of a transistor 200 of FIG. 4. An operational state of the transistor 200 exemplifies the present invention, but the present invention is not limited thereto. Therefore, the operational state of the transistor 200 may be modified.

Referring to FIG. 6A, the spin of the gate electrode 62 is aligned toward the −x axis direction, and the direction is fixed during its operation. The spin of the source electrode 42 is initially aligned in the −y axis direction, and the direction is changeable by the gate electrode 62.

As shown in FIG. 6A, when the spin of the topological insulator 20 is aligned toward the −y axis direction and the voltage is not applied to the gate electrode 62, the spin of the source electrode 42 maintains the −y axis that is the initial state. As a result, the spin of the topological insulator 20 and the spin of the source electrode 42 are aligned in the same direction. Therefore, the current flows through the source electrode 42 and the drain electrode 30. (On state)

On the contrary, as shown in FIG. 6B, when the spin of the topological insulator 20 is aligned toward the −y axis direction and the voltage is applied to the gate electrode 62, the spin of the gate electrode 62 is transmitted to the source electrode 42 and is switched in the −x axis direction in parallel to the gate electrode 62. Therefore, the spin of the source electrode 42 becomes orthogonal to the spin of the topological insulator 20. In this case, the current does not flow through the source electrode 42 and the drain electrode 30. (Off state)

As described above, the transistor 200 of FIG. 4 is tuned on when the gate voltage is 0 volts, while the transistor 200 is turned off when it is 1 volt, and the transistor 200 is operable in a like manner of a p-type transistor without doping.

Accordingly, the n-type-like transistor and the p-type-like transistor may be realized by the spin directions of the gate electrodes 60 and 62 so they are usable as complementarity transistors. Further, by using them, logic circuits such as an inverter, an AND, an OR, or a NOR may be manufactured. The above-described n-type-like transistor and the p-type-like transistor signify realization of operations of the n-MOS or p-MOS without using the actual n-type and p-type semiconductors.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A transistor comprising:
a substrate;
a topological insulator provided on the substrate;
a drain electrode provided on the topological insulator;
a source electrode separated from the drain electrode, provided on the topological insulator, and including a ferromagnetic substance;
a tunnel junction layer provided on the source electrode; and
a gate electrode provided on the tunnel junction layer,
wherein a spin direction of the topological insulator is fixed by a current flowing to a surface thereof, and a spin direction of the source electrode is changed to a predetermined direction by a voltage applied to the gate electrode.

2. The transistor of claim 1, wherein an angle formed between the predetermined direction and the spin direction is 0°, 90°, or 180°.

3. The transistor of claim 1, wherein
when a voltage is not applied to the gate electrode, a spin direction of the source electrode is opposite a spin direction of the topological insulator, and when the voltage is applied to the gate electrode, the spin direction of the source electrode corresponds to the spin direction of the topological insulator.

4. The transistor of claim 1, wherein
the transistor is operated as an n-type transistor or a p-type transistor by a spin direction of the gate electrode and an initial spin direction of the source electrode.

5. The transistor of claim 1, wherein
when the transistor is an n-type-like transistor and a voltage is not applied to the gate electrode, a spin direction of the source electrode forms 90° with a spin direction of the topological insulator, and when the voltage is applied to the gate electrode, the spin direction of the source electrode corresponds to the spin direction of the topological insulator.

6. The transistor of claim 1, wherein
when the transistor is a p-type-like transistor and a voltage is not applied to the gate electrode, a spin direction of the source electrode forms 90° with a spin direction of the topological insulator, and when the voltage is applied to the gate electrode, the spin direction of the source electrode corresponds to the spin direction of the topological insulator.

7. The transistor of claim 1, wherein
the topological insulator includes at least one material selected from Bi₂Se₃, Bi₂Te₃, and Ag₂Te₃.
